(19) United States
(12) Patent Application Publication
(10) Pub. No.: US 2026/0039272 A1
(43) Pub. Date: Feb. 5, 2026

(54) Substrate, Electronic Device, and Module

(71) Applicant: QUANZHOU SANAN INTEGRATED CIRCUIT CO.,LTD., Quanzhou (CN)

(72) Inventors: Minghui FANG, Quanzhou (CN); Wenbi CAI, Quanzhou (CN); Zhonghe LIN, Quanzhou (CN); Shihwei HUANG, Quanzhou (CN); Yilin LIU, Quanzhou (CN)

(21) Appl. No.: 19/274,495

(22) Filed: Jul. 19, 2025

(30) Foreign Application Priority Data
Aug. 1, 2024 (CN) 2024110460452

(51) Int. Cl. H03H 9/02

(52) U.S. Cl. CPC H03H 9/02543

(57) ABSTRACT

The present invention discloses a substrate, an electronic device, and a module. The substrate provided by embodiments comprises a carrier substrate formed from a polycrystalline material and including a plurality of grains, wherein the carrier substrate includes a main support surface for supporting a piezoelectric layer and a back surface opposite to the main support surface, wherein the back surface has a surface roughness with a maximum height greater than or equal to 3 μm, and an arithmetic mean height greater than or equal to 0.2 μm; wherein the plurality of grains having a maximum grain size, and the carrier substrate having a thickness of greater than or equal to twice the maximum grain size.

### CROSS-REFERENCE TO RELATED APPLICATION

The present disclosure claims priority to Chinese Patent Application No 202411046045.2 filed Aug. 1, 2024, the contents of which are herein incorporated by reference in its entirety.

### FIELD

This application relates to the field of mobile communication devices and, more particularly, to a substrate, an elastic wave device and a communication module including the elastic wave device.

### BACKGROUND

In certain acoustic wave devices, such as surface acoustic wave (SAW) filters, particularly those employing a composite substrate formed by bonding a piezoelectric layer to a carrier substrate for temperature compensation, the warpage of the carrier substrate used for bonding is a critical parameter. If the warpage is excessive, it will necessitate manual loading and unloading of wafers in subsequent chip fabrication and packaging processes, rendering automatic equipment operations unfeasible. During manufacturing, it is not only essential to ensure an appropriate degree of warpage in the carrier substrate, but also necessary to avoid deterioration in other parameters or performance resulting from adjustments made solely to reduce warpage. Such deterioration may negatively affect process efficiency, cost, or product yield in downstream processes. Due to these challenges, existing technologies currently lack a suitable solution for effectively reducing the substrate warpage without introducing additional trade-offs.

### SUMMARY

Some examples described herein may have an object to provide a substrate capable of achieving appropriate warpage, reduce adverse effects on subsequent processes, and reduce adverse effects on other performance parameters of the product.

In some examples, a substrate is provided, comprising a carrier substrate formed from a polycrystalline material and including a plurality of grains, wherein the carrier substrate a main support surface for supporting a piezoelectric layer and a back surface opposite to the main support surface, wherein the back surface has a surface roughness with a maximum height greater than or equal to 3 μm, and an arithmetic mean height greater than or equal to 0.2 μm; wherein the plurality of grains having a maximum grain size, and the carrier substrate has a thickness of greater than or equal to twice the maximum grain size.

In some examples, an electronic device is provided, comprising:
a substrate, comprising a carrier substrate formed from a polycrystalline material and including a plurality of grains, wherein the carrier substrate has a main support surface for supporting a piezoelectric layer and a back surface opposite to the main support surface, wherein the back surface has a surface roughness with a maximum height greater than or equal to 3 μm, and an arithmetic mean height greater than or equal to 0.2 μm; wherein the plurality of grains having a maximum grain size, and the carrier substrate has a thickness of greater than or equal to twice the maximum grain size;
a piezoelectric layer provided on the main support surface of the carrier substrate; and
an IDT electrode provided on a principal surface of the piezoelectric layer opposite to the carrier substrate.

In some examples, a module is provided that includes a wiring substrate, a plurality of external connection terminals, an integrated circuit component, an inductor, a sealing portion, and the above-described electronic device.

The embodiments of this invention provide at least one or more of the following advantageous effects: By providing a carrier substrate having a specific grain density, enhanced flexural strength can be achieved, which prevents chipping during subsequent bonding processes, thereby ensuring both production quality and efficiency.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a schematic diagram showing the structure of a carrier substrate according to one embodiment.

FIG. 2 is a schematic view showing the transmittance of the carrier substrate in different wavelength bands according to one embodiment of the present invention.

FIG. 3 is a schematic diagram showing the structure of the composite substrate.

FIG. 4 is a schematic diagram showing an electronic device according to the first embodiment.

FIG. 5 is a schematic diagram showing an electronic device according to the second embodiment.

FIG. 6 is a schematic diagram showing an electronic device according to the third embodiment.

FIG. 7 is a schematic diagram showing an electronic device according to the fourth embodiment.

FIG. 8 is a schematic diagram showing a module according to one embodiment.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

In order to make the objectives, features, and advantages of the present invention more clearly understood, specific embodiments of the invention are described in detail below with reference to the accompanying drawings.

To facilitate a better understanding of the technical solutions of the invention for those skilled in the art, the following descriptions of the embodiments of the invention are provided clearly and comprehensively with reference to the accompanying drawings. It should be understood that the described embodiments are only part of the invention and not exhaustive. All other embodiments obtained by those skilled in the art without involving inventive activity, based on the disclosed embodiments, shall fall within the scope of protection of the invention.

It should also be noted that the terms “first,” “second,” and so on, used in the specification, claims, and drawings of the invention, are merely to distinguish similar elements and do not imply a particular sequence or order. These terms can be used interchangeably when appropriate, so that the embodiments of the invention can be implemented in sequences other than those illustrated or described Furthermore, the terms “include”, “comprise” and variations thereof are intended to be non-exclusive For example, a process, method, system, product, or apparatus that comprises a series of steps or elements is not limited to only those explicitly listed but may also include other steps or elements that are inherent or not expressly stated.

Additionally, it should be noted that the division of embodiments in this disclosure is made for ease of explanation and should not be interpreted as limiting. Features of the various embodiments may be combined or referenced where there is no conflict.

An embodiment of the present invention provides a method for manufacturing a carrier substrate. The carrier substrate 11 thus manufactured includes a main support surface 111 for supporting a piezoelectric layer and a back surface 112 opposite to the main support surface 111. The method for manufacturing the carrier substrate includes:
Step S1: Forming an ingot from raw crystalline powder, and processing the ingot into a pre-processed substrate;
Step S2: Performing polishing treatment on two opposite surfaces of the pre-processed substrate, respectively;
Step S3: Performing sandblasting treatment on one of the polished surfaces of the pre-processed substrate to obtain the carrier substrate. The carrier substrate includes the main support surface for supporting the piezoelectric layer.

The raw crystalline powder used in Step S1 may be powder of a polycrystalline material, such as polycrystalline magnesium aluminum spinel, polycrystalline sapphire, polycrystalline aluminum nitride, polycrystalline magnesium oxide, or polycrystalline quartz. In Step S1, the ingot may be formed by cold isostatic pressing (CIP), hot isostatic pressing (HIP), or other techniques, and the pre-processed substrate may be obtained through cutting, grinding, or similar processing.

For example, in Step S2, the two opposite polished surfaces of the pre-processed substrate may be referred to as the first surface and the second surface. The first surface is used in subsequent processes as the main support surface 111 for the piezoelectric layer. The first surface is polished to achieve an arithmetic mean roughness (Sa) of less than or equal to 0.6 nm, ensuring optimal bonding integrity with the piezoelectric layer. Surface roughness characterization in this specification follows ISO 25178 metrics, including:
Sa: Arithmetic mean height
Sz: Maximum height
Sq: Root mean square height
Sp: Maximum peak height.

In conventional techniques, a carrier substrate is obtained by polishing only the surface intended for bonding with the piezoelectric layer (i.e., the first surface of the pre-processed substrate in the present application). However, it has been discovered during manufacturing that such a process often results in a substrate with large warpage, which makes automatic handling by equipment difficult and increases manufacturing complexity. Moreover, the total thickness variation (TTV) of such substrates can only reach approximately 2 μm, failing to achieve smaller TTV values such as 1 μm or less. In the present embodiment, after processing through Step S2, the pre-processed substrate achieves a warpage of less than 200 μm, thereby lowering manufacturing difficulty. Additionally, the surface TTV can be reduced to 1 μm or less, which helps to improve the thickness uniformity of the piezoelectric layer in subsequent processing.

In continuation, Step S3 involves sandblasting the second surface of the pre-processed substrate. After sandblasting, the second surface becomes the back surface 112 of the carrier substrate 11. The sandblasting process breaks the grains at the second surface to roughen it, so that the surface roughness Sz of the back surface 112 can meet the target requirement, thereby contributing to a lower warpage. The surface roughness Sz referred to herein corresponds to the maximum height Sz defined in ISO 25178.

In the packaging process of acoustic wave devices, alignment of chips is necessary. Infrared sensors, which are a type of photoelectric sensor, are typically used for this alignment. These sensors first convert variations in the object being measured into changes in optical signals, and then further transform these optical signals into electrical signals through photoelectric components. However, when the measured object has high optical transmittance and low reflectivity, the detection signal may not be received, making it difficult to determine the shape and position of the object. Therefore, if the carrier substrate 11 has high transmittance, the light emitted by the alignment equipment may pass through the substrate, resulting in alignment failure.

In this embodiment, both surfaces of the pre-processed substrate are first polished, and then the surface that becomes the back surface 112 of the carrier substrate 11 is roughened by sandblasting. This double-sided polishing enables the simultaneous achievement of lower warpage and lower TTV, and the subsequent sandblasting process reduces the optical transmittance of the carrier substrate 11. As a result, both low warpage and low TTV are achieved while also avoiding alignment difficulties in downstream processing.

In Step S3, the surface roughness of the sandblasted surface is measured. When the measured roughness reaches the target range, Step S3 is terminated, and the carrier substrate 11 is obtained.

In some embodiments, the target range for surface roughness after sandblasting may be Sz≥3 μm and Sa>0.2 μm. The carrier substrate 11 thus obtained has a back surface 112 with a specified surface roughness Sz that can reduce warpage. In addition, the specified surface roughness Sa can effectively reflect and scatter bulk waves, suppress noise, and reduce alignment difficulties.

In other embodiments, the target surface roughness Sz after sandblasting may be greater than or equal to the average grain size of the pre-processed substrate. The pre-processed substrate includes multiple grains with grain sizes ranging from 1 to 100 μm. That is, the substrate may contain grains of various sizes, such as 10 μm, 25 μm, 40 μm, 50 μm, 60 μm, and 100 μm, where the minimum grain size is not less than 1 μm (≥1 μm), and the maximum grain size does not exceed 100 μm (≤100 μm). The average grain size refers to the weighted average of the grain sizes of the grains in the pre-processed substrate. The average grain size is determined by statistically analyzing grain dimensions across multiple sampled areas of the pre-support substrate and computing the arithmetic mean of all measured grain sizes.

In some embodiments, the sandblasting pressure in Step S3 is selected to be in the range of 0.2-0.6 MPa. The particle size of the abrasive used for sandblasting is 1200-1800 mesh. The abrasive may be any one or a combination of high-hardness materials such as silicon carbide, aluminum oxide, or boron carbide.

In some embodiments, the thickness of the pre-processed substrate obtained in Step S1 is greater than or equal to twice the maximum grain size. The thickness of the pre-processed substrate is the distance between the first surface and the second surface. For example, if the grain size ranges from 5 to 60 μm, and the maximum grain size is 60 μm, then the thickness of the pre-processed substrate should be greater than or equal to 120 μm to facilitate the sandblasting process in Step S3.

In some embodiments, the transmittance of the resulting carrier substrate 11 is measured after Step S3. If the measured transmittance is less than 9% in the wavelength range of 240-780 nm and less than 0.1% in the wavelength range below 550 nm, the carrier substrate 11 is considered more favorable for accurate alignment in subsequent processes.

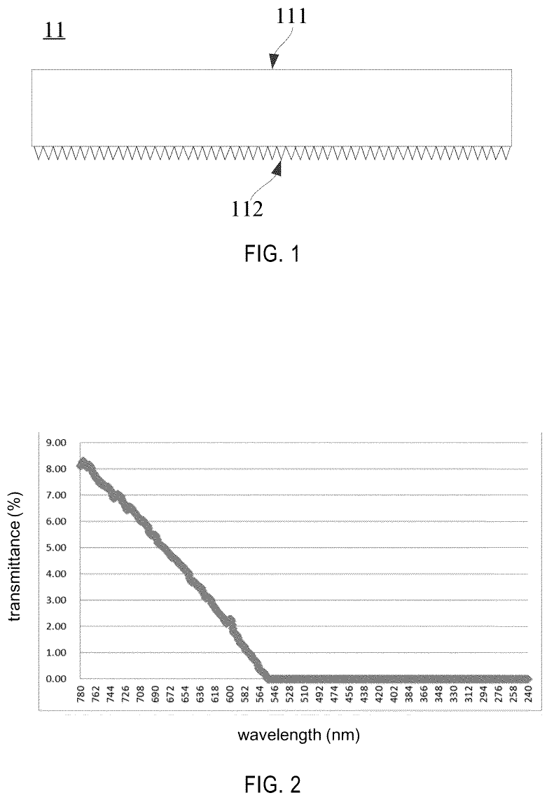

Based on the above-described method, as shown in FIG. 1, a carrier substrate 11 may be obtained. The carrier substrate 11, formed of a polycrystalline material, includes a main support surface 111 for supporting a piezoelectric layer and a back surface 112 opposite to the main support surface. The back surface 112 of the carrier substrate 11 has a specified surface roughness Sz.

For example, the surface roughness Sz of the back surface 112 may be greater than or equal to 3 μm, and the surface roughness Sa may be greater than or equal to 0.2 μm. Alternatively, the surface roughness Sz of the back surface 112 may be greater than or equal to the average grain size of the carrier substrate.

As an example, the carrier substrate 11 may be made of a polycrystalline material such as polycrystalline magnesium aluminum spinel, polycrystalline sapphire, polycrystalline aluminum nitride, polycrystalline magnesium oxide, or polycrystalline quartz.

The carrier substrate 11 includes a plurality of grains. For example, the grain sizes may range from 1 to 100 μm, and the grains may have various sizes such as 10 μm, 25 μm, 40 μm, 50 μm, 60 μm, or 100 μm. The minimum grain size is not less than 1 μm (≥1 μm), and the maximum grain size is not more than 100 μm (≤100 μm). The average grain size of these grains corresponds to the average grain size of the carrier substrate 11. For instance, if the average grain size is 3 μm, then the surface roughness Sz of the back surface 112 is greater than or equal to 3 μm. If the average grain size is 6 μm, then the surface roughness Sz is greater than or equal to 6 μm.

Table 1 shows the average grain size, the surface roughness Sz of the back surface 112, and the warpage of the carrier substrate 11 for several examples according to embodiments of the present invention.

TABLE 1

| Average Grain Size | Sz | Warpage |
|---|---|---|
| 3.0 μm | 2.3 μm | 356 μm |
| 3.0 μm | 3.4 μm | 142 μm |
| 3.0 μm | 6.6 μm | 156 μm |
| 3.0 μm | 7.5 μm | 138 μm |

### Average Grain Size Sz Warpage

As shown in Table 1, when the surface roughness Sz is 2.3 μm, which is less than the average grain size, the warpage exceeds 200 μm. When the surface roughness Sz exceeds 3.4 μm, i.e., greater than the average grain size, the warpage remains below 200 μm. Therefore, in this embodiment, setting the surface roughness Sz greater than the average grain size is advantageous for achieving reduced warpage.

Table 2 shows the relationship between the average grain size of the carrier substrate 11, the surface roughness Sa of the back surface 112, and the transmittance (for light with wavelengths up to 780 nm).

TABLE 2

| Average Grain Size | Sz | Sa | Transmittance T % |
|---|---|---|---|
| 3.0 μm | 2.3 μm | 0.2 μm | 16.30% |
| 3.0 μm | 3.4 μm | 0.4 μm | 8.90% |
| 3.0 μm | 6.6 μm | 0.6 μm | 7.70% |
| 3.0 μm | 7.5 μm | 0.8 μm | 6.50% |

According to Table 2, when the surface roughness Sz of the back surface 112 is less than 3 μm and the surface roughness Sa reaches 0.2 μm, the transmittance is 16.30%, which is relatively high. When the surface roughness Sz exceeds 3.4 μm and Sa exceeds 0.4 μm, the transmittance drops below 8.90%. As the surface roughness Sz and Sa increase, the reflectance gradually improves, thereby reducing alignment difficulty in subsequent processing steps.

The carrier substrate 11 provided in the embodiments has a specific surface roughness Sz that enables the warpage of the carrier substrate 11 to be reduced to 200 μm or less. Combined with a specific surface roughness Sa, the transmittance can be kept low. Under this specific surface roughness Sa, the carrier substrate 11 can effectively reflect and scatter bulk waves, thereby suppressing spurious signals. Additionally, it helps to avoid alignment difficulties during subsequent processes.

In one embodiment of the present invention, as shown in FIG. 2, the carrier substrate 11 has a transmittance of less than 9% for light in the wavelength range of 240-780 nm. More specifically, the transmittance is less than 0.1% for light with wavelengths shorter than 550 nm, approaching zero, which further reduces the difficulty of alignment and ensures efficiency in subsequent processing.

In some embodiments, the thickness of the carrier substrate 11 is greater than or equal to twice the maximum grain size of the carrier substrate 11. For example, if the grain size of the crystals in the carrier substrate 11 ranges from 5 μm to 60 μm (i.e., the minimum is not less than 5 μm, and the maximum is not more than 60 μm), then the maximum grain size is 60 μm, and the substrate thickness should be at least 120 μm. The thickness of the carrier substrate 11 refers to the distance between the main support surface 111 and the back surface 112.

In some embodiments, the surface roughness Sa of the main support surface 111 in the carrier substrate 11 is less than or equal to 0.6 nm, where Sa corresponds to the arithmetic mean height defined in ISO 25178.

In some embodiments, the warpage of the carrier substrate 11 is less than or equal to 200 μm.

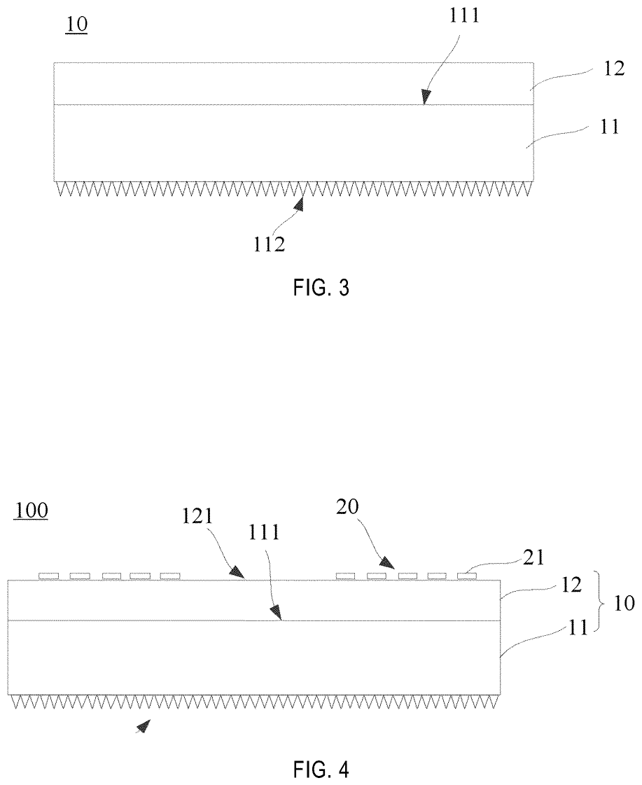

An embodiment of the present invention also provides a composite substrate 10, as shown in FIG. 3. The composite substrate 10 includes a piezoelectric layer 12 and the carrier substrate 11 as described above or prepared by the above-described method. The piezoelectric layer 12 is disposed on the main support surface 111 of the carrier substrate 11 and is bonded thereto. The bonding can be achieved via van der Waals forces. The piezoelectric layer 12 may be composed of lithium tantalate or lithium niobate.

The composite substrate 10 can be formed by first preparing the carrier substrate 11 and piezoelectric layer 12 separately and then bonding them together, or by the method provided in the embodiment described below.

The method for fabricating the composite substrate includes:
Step S1: Forming an ingot using raw crystal powder and processing the ingot into a preprocessed substrate;
Step S2: Polishing the two opposite surfaces of the preprocessed substrate;
Step S4: Bonding the polished preprocessed substrate with a piezoelectric wafer;
Step S5: Sandblasting the surface of the preprocessed substrate opposite to the bonded piezoelectric wafer to obtain the composite substrate.

The specific procedures of steps S1 and S2 are described in detail in the earlier carrier substrate preparation method. In Step S4, the piezoelectric wafer may be obtained by slicing, grinding, polishing, and thinning a lithium tantalate ingot. Prior to Step S5, Step S6 may be performed to thin and polish the piezoelectric wafer to obtain a piezoelectric layer 12 of target thickness, for example, 3 μm.

According to the above description of Step S2, since the total thickness variation (TTV) of the preprocessed substrate after Step S2 can be reduced to 1 μm or less, the thickness of the piezoelectric layer 12 in Step S6 can be controlled within 3±0.3 μm, i.e., 2.7 to 3.3 μm. Step S5 corresponds to Step S3 but is performed after bonding the preprocessed substrate with the piezoelectric wafer, whereas Step S3 is performed before bonding.

After sandblasting in Step S5, the preprocessed substrate becomes the carrier substrate 11, with the treated surface becoming the back surface 112.

The fabrication method of the composite substrate provided in this embodiment achieves low warpage and TTV through double-sided polishing in Step S2 and simultaneously reduces the transmittance of the composite substrate in Step S5. This helps avoid alignment difficulties in subsequent processes while maintaining low warpage and TTV.

Moreover, in the fabrication method provided in this embodiment, it is unnecessary to further thin the back surface of the preprocessed substrate or the carrier substrate 11 after Step S5, as the sandblasting already achieves the desired transmittance and surface roughness. This processing method also reduces warpage, allowing the warpage of the carrier substrate in the composite substrate 10 to be 200 μm or less, thereby providing a broader process window for backend packaging.

As shown in FIG. 4, another embodiment of the present invention provides an electronic device 100 that includes the above-described carrier substrate 11 or composite substrate 10. The carrier substrate 11 may be fabricated by the aforementioned method, and the composite substrate 10 may be obtained by the fabrication method described above.

In the composite substrate 10, the piezoelectric layer 12 includes a front surface 121 facing away from the carrier substrate 11. The electronic device 100 further includes electrodes 20 disposed on the front surface 121. The electrodes 20 include an IDT electrode 21 (interdigital transducer). The electronic device 100 may be a SAW device and benefits from the same effects as the carrier substrate 11 in the above embodiments.

### Second Embodiment

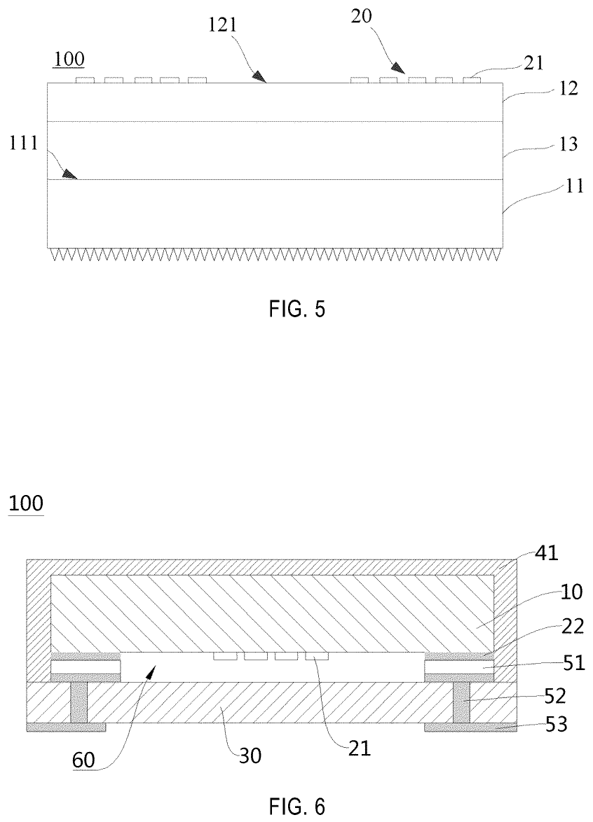

FIG. 5 is a schematic diagram showing an electronic device according to the second embodiment. Referring to FIG. 5, the electronic device 100 (composite substrate 10) further includes an intermediate layer 13, which is disposed between the piezoelectric layer 12 and the carrier substrate 11. The intermediate layer 13 has an acoustic velocity of lower than that of the piezoelectric layer 12. That is, bulk waves propagate more slowly in the intermediate layer 13 compared to the piezoelectric layer 12. By incorporating the low-velocity intermediate layer 13, acoustic wave velocity is reduced, energy is concentrated within the low-velocity medium (i.e., intermediate layer 13), thereby lowering loss and increasing the quality factor (Q).

The intermediate layer 13 may be formed of silicon oxide, silicon oxynitride, tantalum oxide, or any material primarily composed of these. In some embodiments, silicon oxide is used for the intermediate layer, and lithium tantalate is used for the piezoelectric layer 12. Since lithium tantalate exhibits a negative temperature coefficient in its elastic constants and silicon dioxide has a positive temperature coefficient, this configuration reduces the absolute value of the temperature coefficient of frequency (TCF) of the acoustic wave device.

Furthermore, silicon dioxide has a lower acoustic impedance than lithium tantalate, which enhances the electromechanical coupling coefficient of the device.

In some embodiments, the thickness of the intermediate layer 13 is greater than or equal to 0.5λ, where λ is the wavelength of the acoustic wave determined by the electrode period of the IDT electrode 21. More specifically, the thickness of the intermediate layer 13 may range from 0.6 to 0.8λ. In some embodiments, the thickness of the piezoelectric layer 12 is less than or equal to 2λ, and preferably less than 1λ.

In a specific embodiment, λ is 2.25 μm, the thickness of the piezoelectric layer 12 ranges from 0.1λ to 1λ, and the thickness of the intermediate layer 13 is 0.6λ.

The electronic device 100 provided in this embodiment may employ a Chip Scale Package (CSP) or a Wafer Level Package (WLP).

### Third Embodiment

Referring to FIG. 6, which is a schematic structural diagram of an electronic device 100 adopting a CSP package. The electronic device 100 includes a component (including the composite substrate 10 and electrode 20), a package substrate 30, a first sealing structure 41, and a first external terminal electrode 53. The package substrate 30 is arranged opposite the surface of the component having the electrode 20, i.e., the principal surface 121 of the piezoelectric layer 12, with a gap 60 formed between the package substrate 30 and the principal surface 121.

The first sealing structure 41 is disposed on the side of the package substrate 30 facing the component, covering the side surfaces and the back surface of the component opposite to the package substrate 30, thereby sealing the gap 60 and the component itself. The electrode 20 includes an electrode pad 22 electrically connected to the IDT electrode 21. The electrode pad 22 is electrically connected via a bump 51 to a first conductive portion 52 in the wiring pattern on the package substrate 30. The first conductive portion 52 is connected to a first external terminal electrode 53 disposed on the side of the package substrate 30 opposite the component, thereby enabling electrical connection between the electronic device 100 and an external device, via the first external terminal electrode 53.

The materials of the package substrate 30 and the first sealing structure 41 may be selected from commonly used substrate and sealing materials in conventional CSP packaging. The electrode pad 22, bump 51, first conductive portion 52, and first external terminal electrode 53 are made of conductive materials. This embodiment is not limited to the examples described above.

### Fourth Embodiment

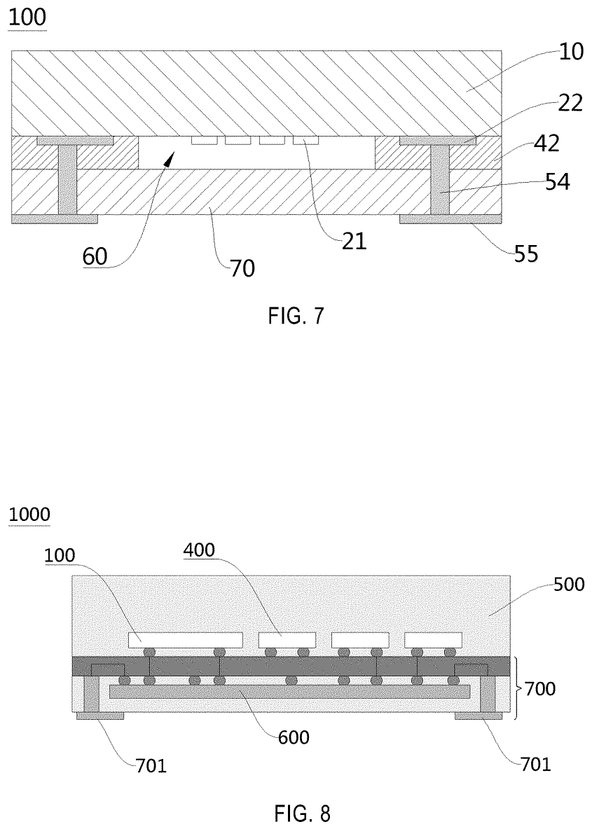

Referring to FIG. 7, which is a schematic structural diagram of an electronic device 100 adopting a WLP package. The electronic device 100 includes a component (including the composite substrate 10 and electrode 20), a cap 70, a second sealing structure 42, and second external terminal electrodes 55. The cap 70 is arranged opposite the surface of the component having the electrode 20 (i.e., the principal surface 121 of the piezoelectric layer 12), with a gap 60 formed between the cap 70 and the principal surface 121.

The electrode includes an electrode pad 22 electrically connected to the IDT electrode 21. The region on the principal surface 121 where the IDT electrode 21 is disposed is referred to as the active region. The second sealing structure 42 is disposed between the cap 70 and the component and surrounds the active region. The second sealing structure 42 encloses the electrode pad 22 to seal the component. A second external terminal electrode 55 disposed on the surface of the cap 70 opposite the component is electrically connected to the electrode pad 22 via a second conductive portion 54 passing through the cap 70 and the second sealing structure 42, thereby enabling the electronic device 100 to be electrically connected to an external device via the second external terminal electrode 55.

The materials of the cap 70 and the second sealing structure 42 may be selected from cover materials and sealing materials commonly used in conventional WLP packaging. The electrode pad 22, second conductive portion 54, and second external terminal electrode 55 are made of conductive materials. This embodiment is not limited thereto.

Referring to FIG. 8, the invention also provides a module 1000 including a wiring substrate 700, a plurality of external connection terminals 701, an integrated circuit component 600, an electronic device 100 (including a composite substrate 10), an inductor 400, and a sealing portion 500. The external connection terminals 701 are formed on one surface of the wiring substrate 700 and are mounted on the motherboard of a predetermined mobile communication terminal. The integrated circuit component 600 (also referred to as IC) is mounted inside the wiring substrate 700 and includes a switch circuit and a low-noise amplifier. The electronic device 100 is mounted on the main surface of the wiring substrate 700. The inductor 400 is used for impedance matching and may be an Integrated Passive Device (IPD). The sealing portion 500 seals the electronic device 100 and other electronic components on the wiring substrate 700.

The module 1000 provided in this embodiment includes the electronic device 100, which in turn includes the carrier substrate 11 and provides the same effects as described in the previous embodiments. Detailed descriptions are omitted here for brevity.

The foregoing description merely represents preferred embodiments of the present invention and is not intended to limit the invention in any way Although the invention has been disclosed through the above embodiments, those skilled in the art may make minor modifications or equivalent changes without departing from the scope of the invention All such modifications, equivalent alterations, and improvements shall fall within the scope of the present invention as defined by its technical essence. Of course, the present invention is not limited to the embodiments described above, but rather encompasses all embodiments capable of achieving the objectives of the invention. It should be understood that the present invention includes all implementations that achieve the objectives described herein, and is not restricted solely to the specific embodiments disclosed.

Although various aspects of some embodiments have been described, it will be readily apparent to those skilled in the art that various modifications, improvements, and enhancements may be made. Such modifications, improvements, and enhancements are intended to be part of the invention and fall within the scope of this disclosure.

It should be understood that the embodiments of the methods and devices described herein are not limited to the configurations and arrangements illustrated or described above The methods and devices may be realized in other forms and may be implemented or carried out in various ways.

The specific examples provided are for illustrative purposes only and are not intended to be limiting in any way.

The expressions and terms used in this disclosure are for the purpose of illustration and should not be construed as limiting Terms such as “comprise,” “include,” “have,” “contain,” and variations thereof are intended to include the items listed thereafter as well as equivalents and additional items.

References to “or” are intended to be inclusive, meaning that any of the listed terms may apply individually, in combination, or collectively.

Directional expressions such as front, back, top, bottom, left, right, vertical, horizontal, inside, and outside are used merely for the sake of descriptive convenience Such expressions do not restrict the components of the invention to any particular spatial position or orientation Accordingly, the above descriptions and drawings are merely illustrative in nature.

What is claimed is:

1. A substrate, comprising a carrier substrate formed from a polycrystalline material and including a plurality of grains, wherein the carrier substrate includes a main support surface for supporting a piezoelectric layer and a back surface opposite to the main support surface, wherein the back surface has a surface roughness with a maximum height greater than or equal to 3 μm, and an arithmetic mean height greater than or equal to 0.2 μm; wherein the plurality of grains having a maximum grain size, and the carrier substrate having a thickness of greater than or equal to twice the maximum grain size.

2. The substrate according to claim 1, wherein the maximum height of the surface roughness of the back surface is greater than or equal to an average grain size of the carrier substrate.

3. The substrate according to claim 1, wherein the main support surface has a surface roughness with an arithmetic mean height of less than or equal to 0.6 nm.

4. The substrate according to claim 1, wherein the carrier substrate has a warpage of less than or equal to 200 μm.

5. The substrate according to claim 1, wherein the main support surface has a total thickness variation of 1 μm or less.

6. The substrate according to claim 1, wherein the carrier substrate has a transmittance of less than 9% in a wavelength band of 240 to 780 nm.

7. The substrate according to claim 6, wherein the carrier substrate has a transmittance of less than 0.1% in a wavelength band below 550 nm.

8. The substrate according to claim 1, wherein the carrier substrate is formed from a material selected from the group consisting of polycrystalline magnesium aluminum spinel, polycrystalline sapphire, polycrystalline aluminum nitride, polycrystalline magnesium oxide, and polycrystalline quartz.

9. The substrate according to claim 1, wherein the plurality of grains has a minimum grain size of 1 μm or more, and a maximum grain size of 100 μm or less.

10. The substrate according to claim 1, further comprising a piezoelectric layer provided on the main support surface of the carrier substrate.

11. The substrate according to claim 10, further comprising an intermediate layer provided between the carrier substrate and the piezoelectric layer, wherein the intermediate layer an acoustic velocity lower than that of the piezoelectric layer.

12. The substrate according to claim 10, further comprising an intermediate layer provided between the carrier substrate and the piezoelectric layer, wherein the intermediate layer has a positive temperature coefficient.

13. The substrate according to claim 10, further comprising an intermediate layer provided between the carrier substrate and the piezoelectric layer, wherein the intermediate layer comprises a material selected from silicon oxide, silicon oxynitride, tantalum oxide, or materials predominantly composed thereof.

14. An electronic device comprising:
a substrate, comprising a carrier substrate formed from a polycrystalline material and including a plurality of grains, wherein the carrier substrate includes a main support surface for supporting a piezoelectric layer and a back surface opposite to the main support surface, wherein the back surface has a surface roughness with a maximum height greater than or equal to 3 μm, and an arithmetic mean height greater than or equal to 0.2 μm; wherein the plurality of grains having a maximum grain size, and the carrier substrate having a thickness of greater than or equal to twice the maximum grain size;
a piezoelectric layer provided on the main support surface of the carrier substrate; and
an IDT electrode provided on a principal surface of the piezoelectric layer opposite to the carrier substrate.

15. The electronic device according to claim 14, further comprising an intermediate layer provided between the carrier substrate and the piezoelectric layer, wherein the intermediate layer has an acoustic velocity lower than that of the piezoelectric layer.

16. The electronic device according to claim 15, wherein the intermediate layer a thickness of greater than or equal to 0.5λ, where λ is a wavelength of an elastic wave defined by a pitch of the IDT electrode.

17. The electronic device according to claim 15, wherein the intermediate layer has a positive temperature coefficient.

18. The electronic device according to claim 15, wherein the intermediate layer comprises a material selected from silicon oxide, silicon oxynitride, tantalum oxide, or materials predominantly composed thereof.

19. The electronic device according to claim 14, wherein the piezoelectric layer has a thickness of less than or equal to 2λ, where λ is a wavelength of an elastic wave defined by a pitch of the IDT electrode.

20. A module comprising a wiring substrate, a plurality of external connection terminals, an integrated circuit component, an inductor, a sealing portion, and the electronic device according to any one of claim 14.
